(19) United States
(12) Patent Application Publication
(10) Pub. No.: US 2025/0019815 A1
(43) Pub. Date: Jan. 16, 2025

(54) FILM-FORMING METHOD AND FILM-FORMING APPARATUS

(71) Applicant: Tokyo Electron Limited, Tokyo (JP)

(72) Inventors: Shimon OTSUKI, Iwate (JP); Masahiko KAMINISHI, Iwate (JP); Fumiaki HAYASE, Iwate (JP)

(21) Appl. No.: 18/761,495

(22) Filed: Jul. 2, 2024

(30) Foreign Application Priority Data
Jul. 12, 2023 (JP) 2023-114310

(51) Int. Cl. C23C 8/12; C23C 8/80; H01J 37/32; H01L 21/02

(52) U.S. Cl. CPC C23C 8/12; C23C 8/80; H01J 37/32357; H01J 37/32449; H01L 21/02274; H01L 21/0228; H01J 2237/332; H01L 21/02178; H01L 21/02181; H01L 21/02189; H01L 21/02192

(57) ABSTRACT

A film-forming method is provided for forming a thin film on a substrate. The film-forming method includes (a) adsorbing a raw material gas onto the substrate, (b) supplying an oxidizing gas to the substrate to oxidize the raw material gas, (c) exposing the substrate to a plasma formed using a plasma gas including an argon gas and an oxygen gas, where (c) includes adjusting an output of the plasma to control crystallinity of the thin film formed on the substrate, and (d) repeating (a), (b), and (c) in this order.

### CROSS-REFERENCE TO RELATED APPLICATIONS

This application is based upon and claims priority to Japanese Patent Application No. 2023-114310, filed on Jul. 12, 2023, the entire contents of which are incorporated herein by reference.

### BACKGROUND

### 1. Field of the Invention

The present disclosure relates to film-forming methods and film-forming apparatuses.

### 2. Description of the Related Art

A technique of depositing a hafnium zirconium-based film on a substrate, followed by performing heat processing on the substrate to crystalize the hafnium zirconium-based film has been known (see, for example, Japanese Laid-Open Patent Publication No. 2021-531661).

### SUMMARY

According to one aspect of the present disclosure, a film-forming method for forming a thin film on a substrate includes (a) adsorbing a raw material gas onto the substrate, (b) supplying an oxidizing gas to the substrate to oxidize the raw material gas, (c) exposing the substrate to a plasma formed using a plasma gas including an argon gas and an oxygen gas, where (c) includes adjusting an output of the plasma to control crystallinity of the thin film formed on the substrate, and (d) repeating (a), (b), and (c) in this order.

The object and advantages of the embodiments will be realized and attained by means of the elements and combinations particularly pointed out in the claims.

It is to be understood that both the foregoing general description and the following detailed description are exemplary and explanatory and not restrictive of the invention, as claimed.

### BRIEF DESCRIPTION OF THE DRAWINGS

FIG. 1 is a flowchart illustrating an example of the film-forming method according to the present disclosure;

FIG. 2 is a schematic cross-sectional view illustrating an example of the film-forming apparatus according to the present disclosure;

FIG. 3 is a schematic perspective view illustrating a configuration of a vacuum chamber of the film-forming apparatus of FIG. 2;

FIG. 4 is a schematic plan view illustrating a configuration inside the vacuum chamber of the film-forming apparatus of FIG. 2;

FIG. 5 is a schematic cross-sectional view of the film-forming apparatus of FIG. 2 that is taken concentrically with a rotary table;

FIG. 6 is another schematic cross-sectional view of the film-forming apparatus of FIG. 2;

FIG. 7 is a schematic cross-sectional view illustrating an example of a remote plasma unit;

FIG. 8 is a plan view illustrating a bottom surface of a shower head of the remote plasma unit;

FIG. 9 is a chart depicting a relationship between a thickness of a zirconium oxide film and a peak intensity of X-ray diffraction (XRD); and

FIG. 10 is a chart depicting crystal phase ratios of a zirconium oxide film.

### DETAILED DESCRIPTION

Hereinafter, non-limiting embodiments of the present disclosure will be described with reference to the attached drawings. Throughout the attached drawings, the same or corresponding members or parts are designated by the same or corresponding reference symbols, and redundant description thereof will be omitted.

### [Film-Forming Method]

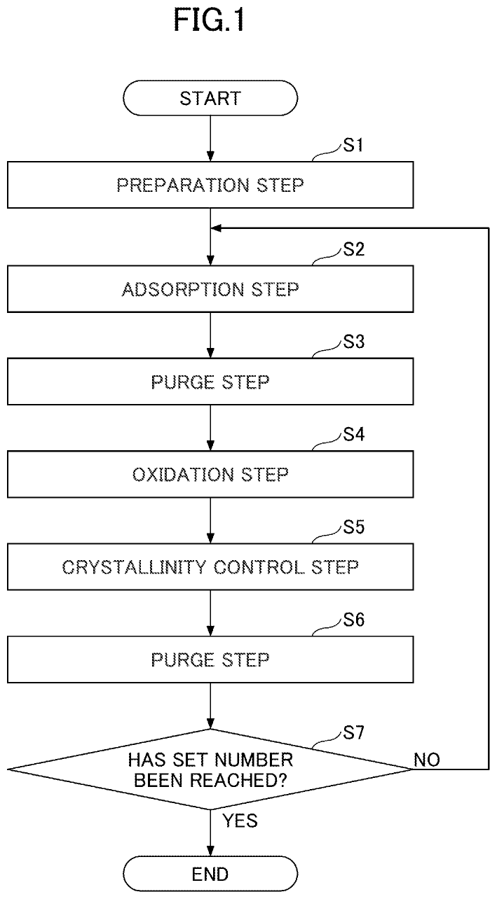

The film-forming method according to the present disclosure will be described with reference to FIG. 1. FIG. 1 is a flowchart illustrating an example of the film-forming method according to the present disclosure. As illustrated in FIG. 1, the film-forming method according to the present disclosure includes a preparation step S1, an adsorption step S2, a purge step S3, an oxidation step S4, a crystallinity control step S5, a purge step S6, and a determination step S7.

The preparation step S1 includes preparation of a substrate. The substrate may be a semiconductor wafer, such as a silicon wafer or the like. The substrate may have recesses, such as trenches, holes, and the like, at a surface thereof.

The adsorption step S2 is performed after the preparation step S1. The adsorption step S2 includes supplying of a raw material gas to a surface of the substrate to adsorb the raw material gas onto the surface of the substrate. The adsorption step S2 may further include maintaining of a temperature of the substrate at a set temperature. The set temperature may be set according to the intended use or purpose.

The raw material gas is, for example, a zirconium (Zr)-containing gas. The raw material gas may be an aluminum (Al)-containing gas, a zirconium-containing gas, a hafnium (Hf)-containing gas, or a lanthanum (La)-containing gas, or a mixed gas including two or more gases selected from the foregoing.

The purge step S3 is performed after the adsorption step S2. The purge step S3 includes supplying of an inert gas to the surface of the substrate to purge the surface of the substrate. The inert gas may be, for example, a nitrogen (Ne) gas. The inert gas may be a noble gas, such as a helium (He) gas, an argon (Ar) gas, and the like.

The oxidation step S4 is performed after the purge step S3. The oxidation step S4 includes supplying of an oxidizing gas to the surface of the substrate to oxidize the raw material gas adsorbed onto the surface of the substrate, thereby forming an oxide film on the surface of the substrate.

The oxidation step S4 may include oxidizing of the raw material gas through thermal oxidation. In this case, crystallinity of the oxide film can be easily controlled in the crystallinity control step S5 that is sequentially performed after the oxidation step S4. The thermal oxidation encompasses that a substrate is subjected to heat processing in an atmosphere including an oxidizing gas to oxidize the raw material gas without using a plasma. The oxidation step S4 may further include maintaining of the substrate at a set temperature. The set temperature may be the same temperature as the temperature of the substrate at the adsorption step S2.

The oxidizing gas is, for example, an ozone (O₃) gas. The oxidizing gas may be an ozone gas, an oxygen (O₂) gas, water (H₂O), or a hydrogen peroxide (H₂O₂) gas, or a mixed gas including two or more gases selected from the foregoing.

The oxide film is, for example, a zirconium oxide film. The oxide film may be any high-k film (high dielectric constant film). The high-k film encompasses a film having a relative permittivity higher than a relative permittivity of a silicon oxide film. The high-k film may be an aluminum oxide film, a hafnium oxide film, a zirconium oxide film, or a lanthanum oxide film, or a laminate film including two or more films selected from the foregoing films.

The crystallinity control step S5 is performed after the oxidation step S4. The crystallinity control step S5 includes exposing of the substrate to a plasma formed using a plasma gas including an argon gas and an oxygen gas. The crystallinity control step S5 includes adjusting of an output of the plasma when the plasma is formed, thereby controlling crystallinity of an oxide film to be formed on the substrate. The output of the plasma encompasses an output of a plasma source used when the plasma is formed. For example, the crystallinity of the oxide film can be lowered by setting the output of the plasma higher than a reference value. For example, the crystallinity of the oxide film can be increased by setting the output of the plasma lower than the reference value. The crystallinity control step S5 may further include maintaining of a temperature of the substrate at a set temperature. The set temperature may be the same temperature as the temperature of the substrate at the adsorption step S2.

The plasma gas is, for example, a mixed gas of an argon gas and an oxygen gas. The mixed gas of the argon gas and the oxygen gas may be also referred to as an Ar/O-gas hereinafter. The plasma gas may further include another noble gas, such as a helium gas or the like.

The plasma is formed, for example, by a remote plasma unit. In this case, radicals or ions included in the plasma formed using the plasma gas easily reach a deep location of each recess formed in the substrate. Therefore, crystallinity of the oxide film formed at the deep location of the recess is easily controlled. The plasma may be also formed by a direct plasma unit. The remote plasma unit and the direct plasma unit each include a plasma source. As the plasma source, for example, an inductively coupled plasma, a capacitively coupled plasma, or a surface-wave plasma source may be used.

The purge step S6 is performed after the crystallinity control step S5. The purge step S6 includes supplying of an inert gas to the surface of the substrate to purge the surface of the substrate. The inert gas may be the same gas as the inert gas used at the purge step S3. The determination step S7 is performed after the purge step S6. The determination step S7 includes determining of whether or not the set number of cycles from the adsorption step S2 to the purge step S6 has been performed. In a case where the number of cycles performed has not reached the set number (No at the determination step S7), a cycle from the adsorption step S2 to the purge step S6 is performed again. In a case where the number of cycles performed has reached the set number (YES at the determination step S7), the process is ended. As described above, a cycle of processes from the adsorption step S2 to the purge step S6 performed in this order is repeated multiple times until the number of cycles performed reaches the set number.

According to the above-described film-forming method of the present disclosure, the adsorption step S2, the oxidation step S4, and the crystallinity control step S5 are repeatedly performed in this order, and the output of the plasma is adjusted at the crystallinity control step S5 to control crystallinity of the oxide film formed on the substrate. Thus, the crystallinity of the oxide film can be easily controlled.

During repetition of the cycle of the processes from the adsorption step S2 to the purge step S6 performed in this order, the output of the plasma at the crystallinity control step S5 may be changed. In this case, crystallinity of the oxide film can be controlled in a film thickness direction.

### [Film-Forming Apparatus]

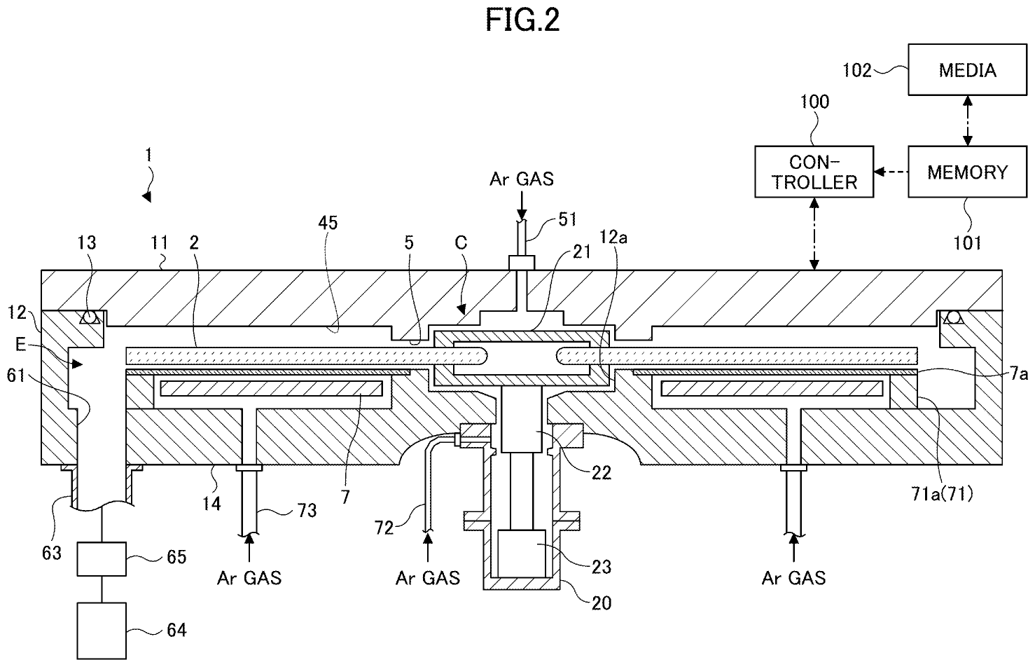

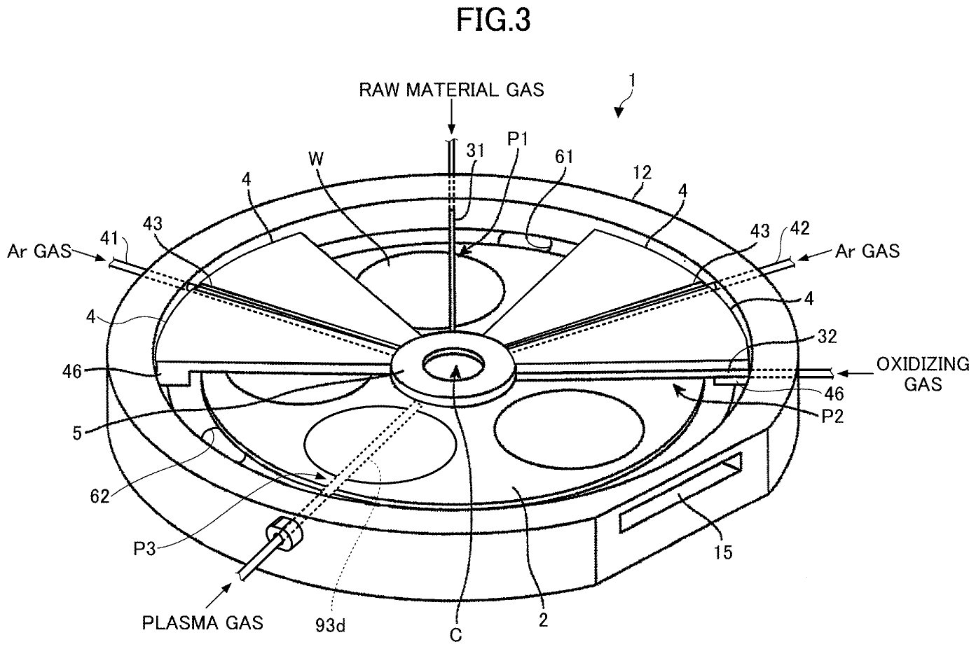

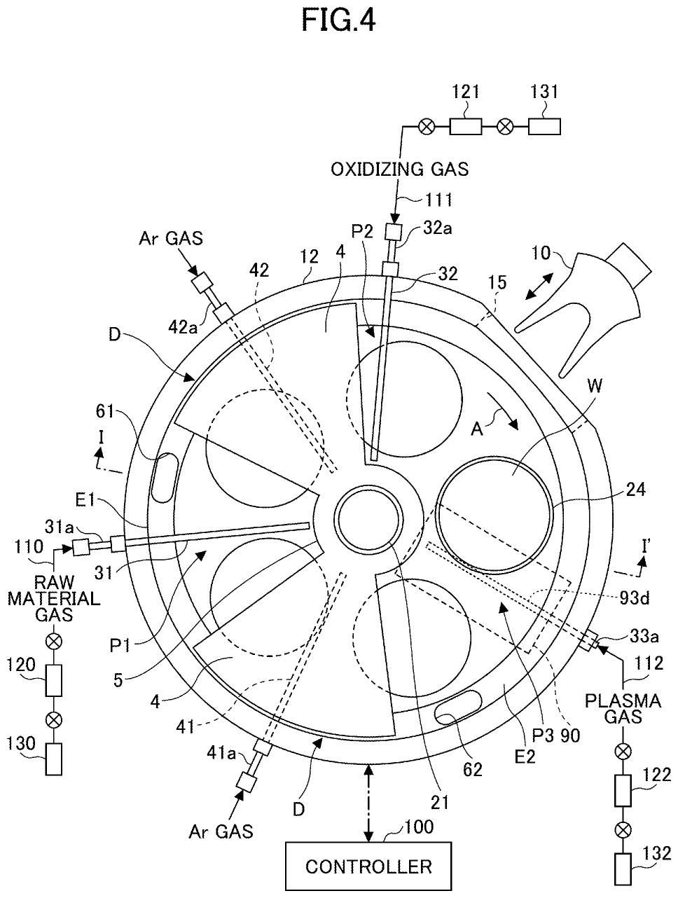

A configuration of the whole film-forming apparatus according to the present disclosure will be described with reference to FIGS. 2 to 8. FIG. 2 is a schematic cross-sectional view illustrating an example of the film-forming apparatus according to the present disclosure. FIG. 3 is a schematic perspective view illustrating a configuration inside a vacuum chamber 1 of the film-forming apparatus of FIG. 2. FIG. 4 is a schematic plan view illustrating the configuration inside the vacuum chamber 1 of the film-forming apparatus of FIG. 2. FIG. 2 is a cross-sectional view taken along the line I-I′ of FIG. 4. In FIGS. 3 and 4, illustration of a top plate 11 is omitted.

As illustrated in FIGS. 2 to 4, the film-forming apparatus according to the present disclosure includes the vacuum chamber 1 and a rotary table 2.

The vacuum chamber 1 is a flat container having a circular planar shape. The vacuum chamber 1 is a process chamber that accommodates one or more substrates W therein and is configured to perform a film-forming process on a surface of each substrate W. The substrates W may be semiconductor wafers. The vacuum chamber 1 includes a top plate 11 and a chamber body 12. The top plate 11 is detachably and airtightly disposed on an upper face of the chamber body 12 via a sealing member 13, such as an O-ring or the like. The chamber body 12 has a cylinder shape having a closed bottom.

The rotary table 2 is disposed inside the vacuum chamber 1. The rotary table 2 has a center of rotation aligned with the center of the vacuum chamber 1. The rotary table 2 is fixed onto a cylindrical core 21 at a central portion of the vacuum chamber. The core 21 is fixed on a top end of a rotary shaft 22 that extends vertically. The rotary shaft 22 is passed through a bottom portion 14 of the vacuum chamber 1, and a bottom end of the rotary shaft 22 is attached to a driver 23. The driver 23 rotates the rotary shaft 22 around a vertical axis. The rotary shaft 22 and the driver 23 are contained in a case that has a shape of a tube where a top face of the tube is open. A flange portion provided at the top face of the case 20 is airtightly attached to a bottom surface of the bottom portion 14 of the vacuum chamber 1 so that the airtightness of an interior of the case 20 is maintained against the exterior of the case 20.

A plurality (five in the illustrated example) of circular recesses 24 are formed in an upper surface of the rotary table 2 in a rotational direction (circumferential direction). A substrate W is mounted on each recess 24. A substrate W is depicted in only one recess 24 in FIG. 4. The recess 24 has an inner diameter slightly larger than a diameter of the substrate W, and a depth substantially equal to a thickness of the substrate W. As the substrate W is set on the recess 24, the upper surface of the substrate W is therefore approximately at the same height as the upper surface of the rotary table 2 (a region where the substrate W is not mounted). For example, through-holes (not illustrated) where three lifting pins are passed through, respectively, are formed in the bottom surface of the recess 24. The three lifting pins support the bottom surface of the substrate W to lift and lower the substrate W with respect to the recess 24.

Above the rotary table 2, gas nozzles 31, 32, 41, and 42, and a gas discharge member 93d of a below-described remote plasma unit 90 are arranged in the rotational direction of the rotary table 2 (the direction indicated with the arrow A in FIG. 4) at set intervals. In the illustrated example, the gas discharge member 93d, the gas nozzle 41, the gas nozzle 31, the gas nozzle 42, and the gas nozzle 32 are arranged in this order from a below-described loading port 15 in the clockwise direction (rotational direction of the rotary table 2). Each of the gas nozzles 31, 32, 41, and 42 is formed of, for example, quartz. Gas inlet ports 31a, 32a, 41a, and 42a are fixed onto an outer circumferential wall of the chamber body 12. The gas inlet ports 31a, 32a, 41a, and 42a are proximal ends of the gas nozzles 31, 32, 41, and 42, respectively. Thus, the gas nozzles 31, 32, 41, and 42 are inserted from the outer circumferential wall of the vacuum chamber 1 into the interior of the vacuum chamber 1 to extend along a radius direction of the chamber body 12 to be parallel to the rotary table 2. A gas supply pipe 92 of the remote plasma unit 90, which is coupled to a below-described gas discharge member 93d, may be coupled to a gas inlet port 33a.

The gas nozzle 31 is coupled to a supply source 130 of a raw material gas via a pipe 110, a flow rate controller 120, and the like. The raw material gas is, for example, a zirconium-containing gas. The raw material gas may be an aluminum-containing gas, a zirconium-containing gas, a hafnium-containing gas, or a lanthanum-containing gas, or a mixed gas including two or more gasses selected from the foregoing.

The gas nozzle 32 is coupled to a supply source 131 of an oxidizing gas via a pipe 111, a flow rate controller 121, and the like. The oxidizing gas is, for example, an ozone gas. The oxidizing gas may be an ozone gas, an oxygen gas, water, or a hydrogen peroxide gas, or a mixed gas including two or more gasses selected from the foregoing.

The gas supply pipe 92 of the remote plasma unit 90 is coupled to a supply source 132 of a plasma gas via a pipe 112, a flow rate controller 122, and the like. The plasma gas includes an argon gas and an oxygen gas. The plasma gas is, for example, an Ar/O₂ gas. The plasma gas may further include another noble gas, such as helium gas or the like.

The gas nozzles 41 and 42 are each coupled to a supply source (not illustrated) of a separation gas via a pipe (not illustrated), a flow rate controlling valve (not illustrated), and the like. The separation gas is, for example, an argon gas. The separation gas may be another noble gas, such as a helium gas or the like, or may be a nitrogen gas.

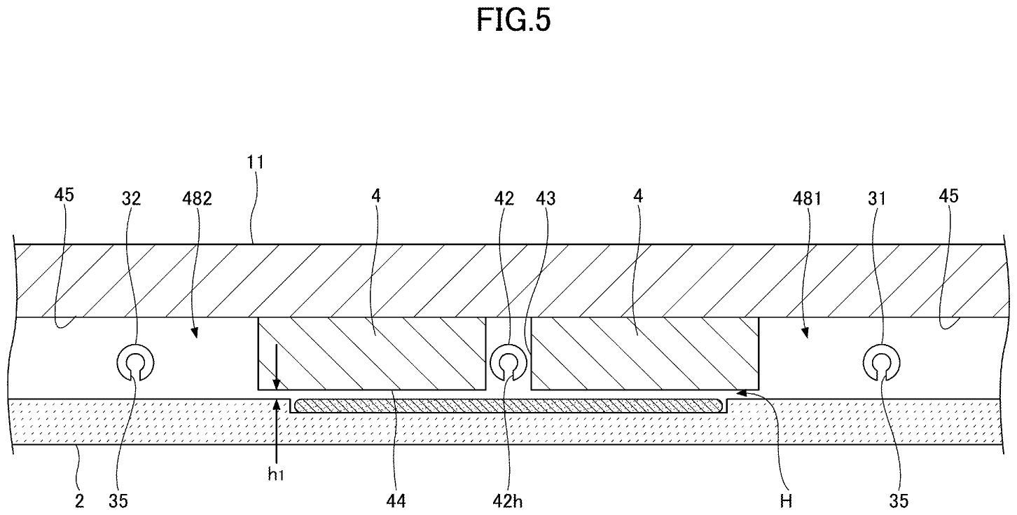

FIG. 5 is a schematic cross-sectional view of the film-forming apparatus of FIG. 2 taken concentrically with the rotary table 2, and illustrates a cross-section of the vacuum chamber, which is taken concentrically with the rotary table 2, and includes a region from the gas nozzle 31 to the gas nozzle 32.

As illustrated in FIG. 5, discharge holes 35 are formed in each of gas nozzles 31 and 32. The discharge holes 35 are aligned in a length direction of each of the gas nozzles 31 and 32, for example, at the intervals of 10 mm. Each discharge hole 35 is open toward the rotary table 2. The gas nozzle 31 discharges a raw material gas from the discharge holes 35 toward an upper surface of the rotary table 2. A region below the gas nozzle 31 functions as an adsorption region P1 for allowing the raw material gas to be adsorbed onto the substrate W. The gas nozzle 32 discharges the oxidizing gas from the discharge holes 35 toward the upper surface of the rotary table 2. A region below the gas nozzle 32 functions as an oxidation region P2 where the raw material gas adsorbed onto the substrate W in the adsorption region P1 is oxidized to form an oxide film. A region below the gas discharge member 93d functions as a plasma region P3 in which the oxide film formed in the oxidation region P2 is exposed to a plasma formed using the plasma gas. The remote plasma unit 90 is disposed above the plasma region P3. In FIG. 4, the remote plasma unit 90 is simplified and illustrated with a dashed line. The remote plasma unit 90 will be described below.

Two projections 4 are disposed inside the vacuum chamber 1. Each projection 4 forms a separation region D together with a corresponding gas nozzle 41 or 42. Each projection 4 has a fan-like planar shape in which a tip of the fan is cut out into an arc shape. The inner arc of the projection is linked with a protrusion 5 (described below). The outer arc of the projection 4 is aligned with an inner circumferential surface of the chamber body 12.

The projection 4 is mounted on the bottom surface of the top plate 11 in a manner such that the projection 4 projects toward the rotary table 2. Thus, a low flat ceiling (referred to as a “first ceiling surface 44” hereinafter), which is the bottom surface of the projection 4, and ceiling surfaces (each referred to as a “second ceiling surface 45” hereinafter) that are higher than the first ceiling surface 44 and are positioned at both sides of the first ceiling surface 44 in the circumferential direction are present inside the vacuum chamber 1. The first ceiling surface 44 has a fan-like planar shape in which a tip of the fan is cut out into an arc shape. A groove 43 is formed in the projection 4. The groove 43 extends in a radius direction at a middle of the projection 4 in the circumferential direction. The gas nozzle 42 is accommodated in the groove 43. Similarly, a groove 43 is formed in the other projection 4. In the groove 43, the gas nozzle 41 is accommodated. The gas nozzles 31 and 32 are disposed in the spaces below the second ceiling surfaces 45, respectively. Each of the gas nozzle 31 and 32 is disposed in the vicinity of the substrate W to be set apart from the second ceiling surface 45. The gas nozzle 31 is disposed in the right space 481 below the second ceiling surface 45. The gas nozzle 32 is disposed in the left space 482 below the second ceiling surface 45.

Discharge holes 42h are formed in the gas nozzle 42. The discharge holes 42h are aligned in a length direction of the gas nozzle 42, for example, at intervals of 10 mm. Each discharge hole 42h is open toward the rotary table 2. The gas nozzle 42 discharges the separation gas from the discharge holes 42h toward the upper surface of the rotary table 2. A configuration of the gas nozzle 41 is the same as the configuration of the gas nozzle 42.

The first ceiling surface 44 forms a separation space H, which is a narrow space, with the rotary table 2. As the separation gas is supplied from the discharge holes 42h, the separation gas is flowed into the space 481 and the space 482 through the separation space H. Since the volume of the separation space H is smaller than the volume of the space 481 and the volume of the space 482, the above flow of the separation gas causes the pressure of the separation space H to be higher than the pressure of the space 481 and the pressure of the space 482. Specifically, the separation space H having the high pressure is formed between the space 481 and the space 482. The separation gas flowed from the separation space H into the space 481 and the space 482 functions as counter flows against the raw material gas from the adsorption region P1 and against the oxidizing gas from the oxidation region P2. Thus, the raw material gas and the oxidizing gas are separated from each other by the separation space H. Therefore, mixing of the raw material gas and the oxidizing gas inside the vacuum chamber 1 is inhibited.

A height h1 of the first ceiling surface 44 with respect to the rotary table 2 is set in a manner such that the pressure of the separation space H is to be higher than the pressure of the space 481 and the pressure of the space 482, considering the internal pressure of the vacuum chamber 1, a rotational speed of the rotary table 2, a feeding rate of the separation gas, and the like, when a film is formed on a substrate W.

A protrusion 5 is disposed at the bottom surface of the top plate 11. The protrusion 5 surrounds the outer periphery of the core 21 to which the rotary table 2 is fixed. The protrusion 5 is continuous with the portion of the projection 4, which is at the side of the center of rotation. The protrusion 5 is configured so that a bottom surface of the protrusion 5 is at the same height as the height of the first ceiling surface 44.

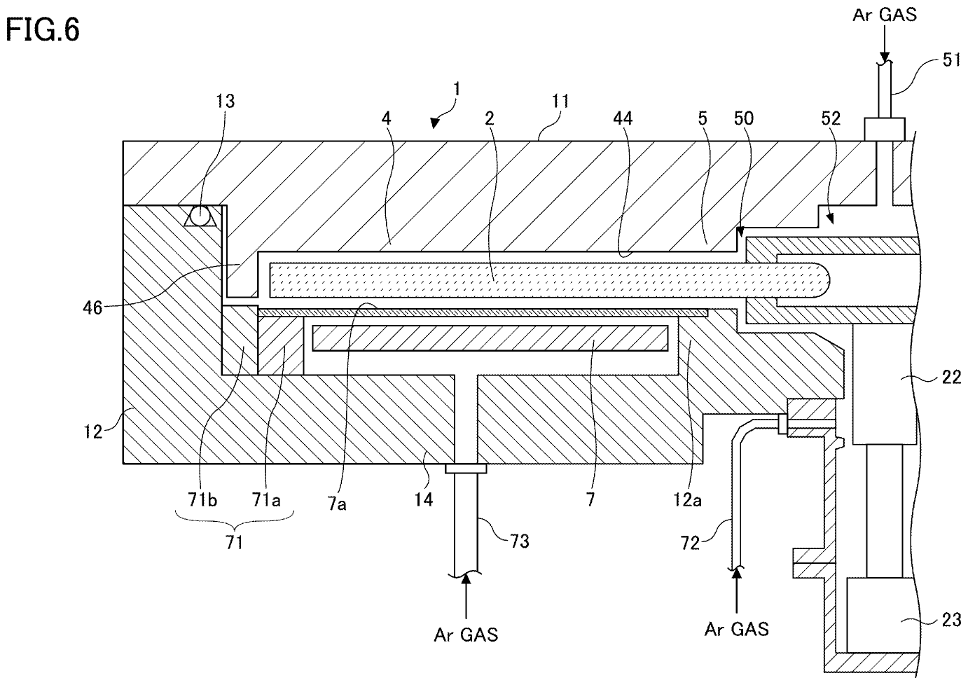

FIG. 6 is a cross-sectional view illustrating a region where the first ceiling surface 44 is disposed. As illustrated in FIG. 6, a bending portion 46 is disposed on a peripheral edge portion of the projection 4 having the fan-like shape. The bending portion 46 is a portion of the projection 4 that is bent like a shape of the letter “L” to face the outer edge surface of the rotary table 2. Like the projection 4, the bending portion 46 inhibits entry of the raw material gas and the oxidizing gas from the both sides of the separation region D to inhibit the raw material gas and the oxidizing gas from mixing with each other.

As illustrated in FIG. 6, the inner circumferential wall of the chamber body 12 is formed as a vertical surface that is arranged to be close to the outer circumferential surface of the bending portion 46 in the separation region D. As illustrated in FIG. 2, in the regions other than the separation region D, the inner circumferential wall of the chamber body 12 is recessed outward, for example, from a portion facing the outer edge surface of the rotary table 2 to the bottom portion 14. For the convenience of the description, the recessed portion having a substantially rectangular cross-sectional shape is described as an exhaust region hereinafter. Specifically, an exhaust region communicating with the adsorption region P1 is described as a first exhaust region E1, and an exhaust region communicating with the oxidation region P2 and the plasma region P3 is described as a second exhaust region E2. A first exhaust port 61 and a second exhaust port 62 are formed in a bottom of the first exhaust region E1 and a bottom of the second exhaust region E2, respectively. Each of the first exhaust port 61 and the second exhaust port 62 is coupled to a vacuum pump 64 via an exhaust pipe 63. A pressure controller 65 is disposed between the vacuum pump 64 and the exhaust pipe 63. The first exhaust port 61 is illustrated in FIG. 2. The second exhaust port 62 has the same configuration as the configuration of the first exhaust port 61 in FIG. 2.

As illustrated in FIGS. 2 and 6, a heater unit 7 is disposed in a space between the rotary table 2 and the bottom portion 14 of the vacuum chamber 1. The heater unit 7 heats a substrate W on the rotary table 2 through the rotary table 2 at a set temperature determined by a process recipe. An annular cover member 71 is disposed below a region in the vicinity of the rim of the rotary table 2. The cover member 71 partitions the interior of the vacuum chamber 1 into the atmosphere that extends from the upper space of the rotary table 2 to the first exhaust region E1 and the second exhaust region E2, and the atmosphere in which the heater unit 7 is disposed, thereby inhibiting entry of gases into the region below the rotary table 2. The cover member 71 includes an inner member 71a and an outer member 71b. The inner member 71a is disposed in a manner such that the inner member 71a faces the outer edge of the rotary table 2 and faces a region slightly outward of the outer edge of the rotary table 2 from the bottom side of the rotary table 2. The inner member 71a surrounds the entire periphery of the heater unit 7 at a position below the outer edge of the rotary table 2 (and below the region slightly outward of the outer edge of the rotary table 2). The outer member 71b is disposed between the inner member 71a and the inner circumferential surface of the vacuum chamber 1. The outer member 71b is disposed in a manner such that the outer member 71b comes close to the bottom of the bending portion 46 formed on the peripheral edge portion of the projection 4 in the separation region D.

The section of the bottom portion 14 that is closer to the rotation center than the space in which the heater unit 7 is disposed is projected upward to be close to the core 21 in the vicinity of the center of the bottom surface of the rotary table 2, thereby forming a protrusion 12a. A narrow space is formed between the protrusion 12a and the core 21, and a small gap is formed between an inner circumferential surface of a through hole, in which the rotary shaft 22 is passed through the bottom portion 14, and the rotary shaft 22. The above narrow spaces are communicated with the case 20. A purge gas supply pipe 72 is attached to the case 20. The narrow spaces are purged with the purge gas supplied from the purge gas supply pipe 72. Purge gas supply pipes 73 are attached to the bottom portion 14 of the vacuum chamber 1. The purge gas supply pipes 73 are arranged below the heater unit 7 in the circumferential direction at set angular intervals. One purge gas supply pipe 73 is illustrated in FIG. 6. The space in which the heater unit 7 is disposed is purged with the purge gas supplied from the purge gas supply pipes 73. The purge gas may be the same gas as the separation gas. A lid member 7a is disposed between the heater unit 7 and the rotary table 2. The lid member 7a covers an area ranging from the inner circumferential wall of the outer member 71b (the upper surface of the inner member 71a) to the upper end of the protrusion 12a in the circumferential direction. The lid member 7a inhibits gasses from entering the region in which the heater unit 7 is disposed. The lid member 7a is formed of, for example, quartz.

A separation gas supply pipe 51 is attached to the center of the top plate 11. The separation gas supply pipe 51 supplies a separation gas into a space 52 between the top plate 11 and the core 21. The separation gas supplied into the space 52 passes through a space 50 between the protrusion 5 and the rotary table 2, which is a narrow gap, to be discharged toward the periphery of the rotary table 2 along the surface of the rotary table 2 where substrates are mounted. The pressure of the space 50 is retained at the pressure higher than the pressure of the space 481 and the pressure of the space 482 by the separation gas. Therefore, the space 50 inhibits the raw material gas supplied to the adsorption region P1 and the oxidizing gas supplied to the oxidation region P2 from passing through the central region C to be mixed with each other. Specifically, the space 50 (or the central region C) functions similarly to the separation space H (or the separation region D).

A loading port 15 is formed in the side wall of the vacuum chamber 1. Loading and discharging of substrates W between an external transfer arm 10 and the rotary table 2 are performed through the loading port 15. The loading port 15 is opened and closed by a gate valve (not illustrated). Loading and discharging of each substrate W is performed between the recess 24 that is in a position facing the loading port 15 and the transfer arm 10. A lifting pin for loading and discharging and a lifting mechanism (both not illustrated) are disposed in a position that corresponds to the loading and discharging position and is below the rotary table 2. The lifting pin passes through the recess 24 to support a bottom surface of a substrate W to lift the substrate W.

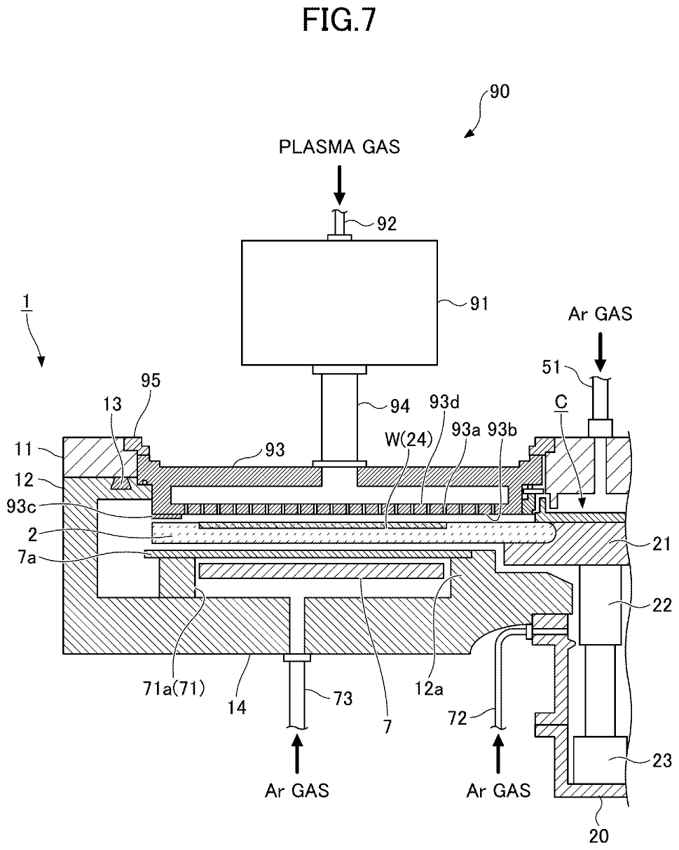

FIG. 7 is a schematic cross-sectional view illustrating an example of the remote plasma unit 90. The remote plasma unit 90 is disposed in the plasma region P3 to face the rotary table 2. The remote plasma unit 90 includes a plasma generator 91, a gas supply pipe 92, a shower head 93, and a pipe 94. A gas nozzle may be used instead of the shower head 93.

The plasma generator 91 is configured to activate the plasma gas supplied from the gas supply pipe 92 with a plasma source. The plasma source is not particularly limited as long as the plasma source can activate the plasma gas. As the plasma source, for example, an inductively coupled plasma, a capacitively coupled plasma, or a surface-wave plasma can be used.

One end of the gas supply pipe 92 is coupled to the plasma generator 91 to supply the plasma gas to the plasma generator 91. The other end of the gas supply pipe 92 is coupled to a supply source 132 of the plasma gas, for example, via an open/close valve and a flow rate controller. The plasma gas is stored in the supply source 132.

The shower head 93 is coupled to the plasma generator 91 via the pipe 94. The shower head 93 supplies the plasma gas activated by the plasma generator 91 into the vacuum chamber 1. The shower head 93 has a fan-like planar shape, and the shower head 93 is pressed downward in the circumferential direction by a press member 95 that is formed to be aligned with the outer edge of the fan-like planar shape of the shower head 93. The press member 95 is fastened to the top plate 11 by bolts and the like (not illustrated). Thus, the interior atmosphere of the vacuum chamber 1 is airtightly retained.

Discharge holes 93a are formed in the shower head 93. The activated plasma gas supplied to the shower head 93 is supplied to the space between the rotary table 2 and the shower head 93 through the discharge holes 93a.

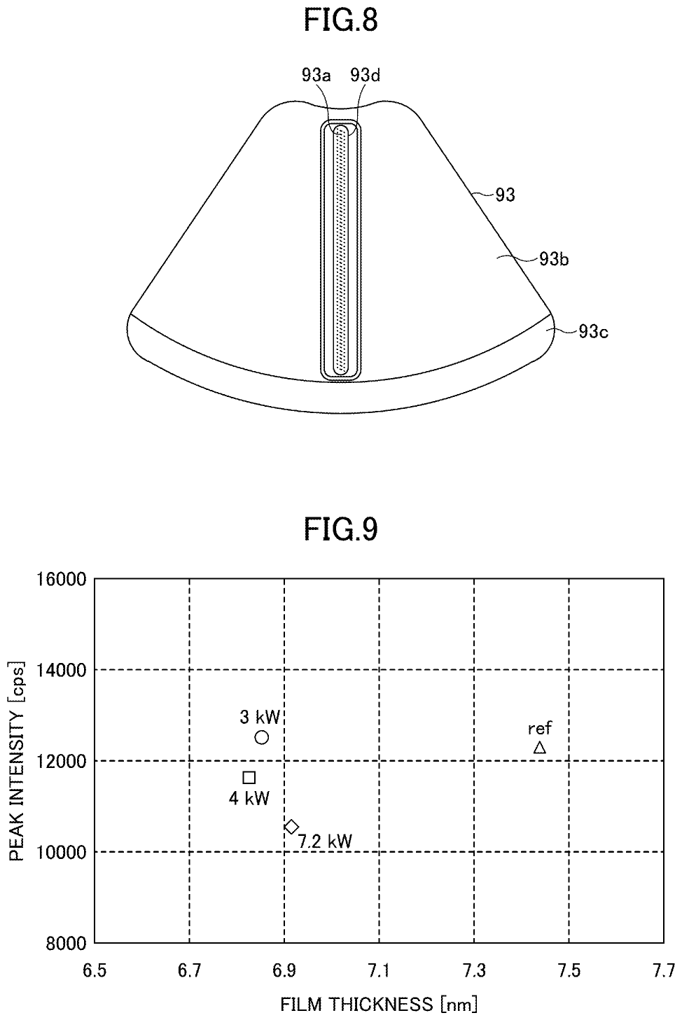

FIG. 8 is a plan view illustrating the bottom surface of the shower head 93 of the remote plasma unit 90. As illustrated in FIG. 8, a downwardly projecting surface 93c may be arranged in a shape of a band along the outer circumference of the bottom surface 93b of the fan-shaped shower head 93. Thus, reduction in the pressure at the outer circumferential side of the plasma region P3 can be uniformly inhibited in the circumferential direction. The discharge holes 93a may be aligned in a radius direction at the middle of the bottom surface 93b of the shower head 93 in the circumferential direction. Thus, the plasma gas can be dispersedly supplied from the center of the rotary table 2 to the outer circumferential side of the rotary table 2. In the present specification, an area of the shower head 93 in which the discharge holes 93a are arranged may be referred to as a gas discharge member 93d.

As described above, the remote plasma unit 90 supplies the activated plasma gas to the substrate W.

As illustrated in FIG. 2, the film-forming apparatus of the present disclosure includes a controller 100. The controller 100 is configured to control an operation of each of devices, units, and/or members of the film-forming apparatus. The controller 100 may be a computer. Programs of the computer used to control an operation of each of devices, units, and/or members of the film-forming apparatus are stored in media 102. The media 102 may be flexible disks, compact disks, hard disks, flash memory disks, DVDs, and the like. The programs stored in the media 102 are loaded onto a memory 101 by a suitable reader, and are then installed on the controller 100.

### [Operations of Film-Forming Apparatus]

Operations of the film-forming apparatus when the film-forming method of the present disclosure is performed will be described. Hereinafter, the operations of the film-forming apparatus will be described through an example where a zirconium oxide film is formed as a thin film.

First, substrates W are respectively mounted on five recesses 24 of the rotary table 2 disposed inside the vacuum chamber 1 of the film-forming apparatus. Specifically, a gate valve (not illustrated) of the film-forming apparatus is opened, and the substrates W are respectively loaded from the outside of the vacuum chamber 1 into the recesses 24 of the rotary table 2 through a loading port 15 by a transfer arm 10. The loading of each substrate W is performed by lifting or lowering lifting pins (not illustrated) from the bottom of the vacuum chamber 1 via through holes formed in the bottom surface of each recess 24, when a corresponding recess 24 is stopped at a position facing the loading port 15. The loading of the substrates W is performed by intermittently rotating the rotary table 2, thereby respectively mounting the substrates W in the five recesses 24 of the rotary table 2.

Next, the inner atmosphere of the vacuum chamber 1 is exhausted. Specifically, the gate valve is closed, and the inner atmosphere of the vacuum chamber 1 is exhausted by a vacuum pump 64 until reaching ultimate vacuum.

Next, an argon gas serving as a separation gas is discharged from the gas nozzles 41 and 42 and the separation gas supply pipe 51 at a set flow rate, and an argon gas serving as a purge gas is discharged from the purge gas supply pipes 72 and 73 at a set flow rate. Then, a zirconium-containing gas serving as a raw material gas is supplied from the gas nozzle 31, an ozone gas serving as an oxidizing gas is supplied from the gas nozzle 32, and an Ar/O₂ gas serving as a plasma gas is supplied from the gas supply pipe 92. Moreover, the remote plasma unit 90 is activated. The remote plasma unit 90 forms a plasma using the Ar/O₂ gas. Moreover, the internal pressure of the vacuum chamber 1 is controlled at a pre-set processing pressure by a pressure controller 65. The substrates W are heated by a heater unit 7, while rotating the rotary table 2 in the clockwise direction. The rotational speed of the rotary table 2 and the temperature of each substrate W are appropriately set according to the intended use or purpose.

By the rotation of the rotary table 2, each substrate W repeatedly passes through the adsorption region P1, the separation region D, the oxidation region P2, the plasma region P3, and the separation region D in this order.

In the adsorption region P1, the adsorption step S2 is performed. In the adsorption region P1, the zirconium-containing gas is supplied from the gas nozzle 31 to a surface of the substrate W so that the zirconium-containing gas is adsorbed onto the surface of the substrate W.

In the separation region D, the purge step S3 is performed. In the separation region D, the argon gas is supplied from the gas nozzle 42 to the surface of the substrate W so that the surface of the substrate W is purged.

In the oxidation region P2, the oxidation step S4 is performed. In the oxidation region P2, the ozone gas is supplied from the gas nozzle 32 to the surface of the substrate W so that the zirconium-containing gas adsorbed onto the surface of the substrate W is oxidized to form a zirconium oxide film on the surface of the substrate W.

In the plasma region P3, the crystallinity control step S5 is performed. In the plasma region P3, the substrate W is exposed to a plasma formed using the Ar/O-gas so that crystallinity of the zirconium oxide film is controlled. Specifically, the crystallinity of the zirconium oxide film is controlled by adjusting the output of the plasma when the plasma is formed.

In the separation region D, the purge step S6 is performed. In the separation region D, the argon gas is supplied from the gas nozzle 41 to purge the surface of the substrate W.

As described above, by the rotation of the rotary table 2, the substrate W is repeatedly passed through the adsorption region P1, the separation region D, the oxidation region P2, the plasma region P3, and the separation region D, thereby forming a zirconium oxide film whose crystallinity is controlled on the surface of the substrate W.

Next, purge is performed. Specifically, the supply of the zirconium-containing gas from the gas nozzle 31 is terminated, and the supply of the ozone gas from the gas nozzle 32 is terminated. Moreover, the supply of the Ar/O₂ gas to the remote plasma unit 90 and the operation of the remote plasma unit 90 are terminated so that the supply of the activated Ar/O₂ gas from the gas discharge member 93d is terminated. The argon gas is supplied from the gas nozzles 41 and 42 and the separation gas supply pipe 51 at a set flow rate, and the argon gas is supplied from the purge gas supply pipes 72 and 73 at a set flow rate. Thus, the vacuum chamber 1 is purged with the argon gas.

Next, the internal atmosphere of the vacuum chamber 1 is released to return back to the atmospheric pressure, and the substrates W on each of which the zirconium oxide film is formed are discharged from the vacuum chamber 1.

According to the above-described operations of the film-forming apparatus, the adsorption step S2, the oxidation step S4, and the crystallinity control step S5 are repeatedly performed on each substrate W in this order in the vacuum chamber 1. Moreover, the output of the plasma of the remote plasma unit 90 is adjusted in the crystallinity control step S5 so that crystallinity of the oxide film formed on each substrate is controlled.

### Examples

The film-forming method according to the present disclosure is performed by the film-forming apparatus according to the present disclosure.

In Examples, a zirconium-containing gas serving as a raw material gas was supplied from the gas nozzle 31, an ozone gas serving as an oxidizing gas was supplied from the gas nozzle 32, and an Ar/O₂ gas serving as a plasma gas was supplied from the gas supply pipe 92. Moreover, the remote plasma unit 90 was actuated to form a plasma using the Ar/O₂ gas. By rotating the rotary table 2, a substrate W was passed through an adsorption region P1, a separation region D, an oxidation region P2, a plasma region P3, and a separation region D in this order to form a zirconium oxide film on a surface of the substrate W. A mixing ratio of the Ar/O-gas was Ar₂O₂=5:3. At the crystallinity control step S5, an output of a plasma was set at three conditions of 3 kilowatt (KW), 4 KW, and 7.2 kW.

For comparison to Examples, the above process of Examples was repeated to form a zirconium oxide film on a surface of the substrate, except that the remote plasma unit 90 was not actuated, and an ozone gas was supplied from the gas supply pipe 92 instead of the Ar/O₂ gas.

Next, a thickness and crystallinity of each of the formed zirconium oxide films were measured. The thickness of each zirconium oxide film was determined by observing a cross-section of the zirconium oxide film by transmission electron microscopy (TEM), and calculating a film thickness based on the observed cross-sectional image. The crystallinity of the zirconium oxide film was evaluated by X-ray diffraction (XRD) and automated crystal orientation mapping for transmission electron microscopy (ACOM-TEM). When a measurement of the X-ray diffraction is performed in a θ-2θ scan mode, a peak derived from a tetragonal crystal of the zirconium oxide film appears at the vicinity of the diffraction angle 2θ of 30°. Thus, the crystallinity of the zirconium oxide film was evaluated by measuring the peak intensity at the diffraction angle 2θ of 30°. According to ACOM-TEM, a phase distribution map of a cross-section of the zirconium oxide film was obtained to determine proportions of the tetragonal crystal, the orthorhombic crystal, and the monoclinic crystal (crystal phase ratios).

FIG. 9 is a chart depicting a relationship between a thickness of the zirconium oxide film and a peak intensity of XRD. In FIG. 9, a horizontal axis denotes a thickness [nanometer (nm)] of the zirconium oxide film measured by TEM, and a vertical axis denotes a peak intensity [count per second (cps)] of the zirconium oxide film measured by XRD at 20 of 30°. In FIG. 9, the circle represents the result of the zirconium oxide film for which the output of the plasma was set at 3 kW, the square represents the result of the zirconium oxide film for which the output of the plasma was set at 4 kW, the diamond represents the result of the zirconium oxide film for which the output of the plasma was set at 7.2 kW, and the triangle represents the result of Comparative Example (output of plasma: 0 kW).

As depicted in FIG. 9, it was demonstrated that the thickness of the zirconium oxide film was substantially the same with any plasma output of 3 KW, 4 KW, or 7.2 kW, and the peak intensity of XRD was increased by reducing the plasma output. These results indicate that crystallinity of the zirconium oxide film was increased by reducing the plasma output. As described above, crystallinity of the zirconium oxide film can be controlled by adjusting an output of a plasma without adversely affecting a thickness of the zirconium oxide film.

Moreover, as depicted in FIG. 9, it was demonstrated that Examples could achieve the similar level of the peak intensity of XRD to the peak intensity of Comparative Example with the thinner thickness of the zirconium oxide film than the thickness of the zirconium oxide film of Comparative Example. These results indicate that a thin film of the zirconium oxide film can be formed, while maintaining crystallinity of the zirconium oxide film, by performing the crystallinity control step S5 after the oxidation step S4.

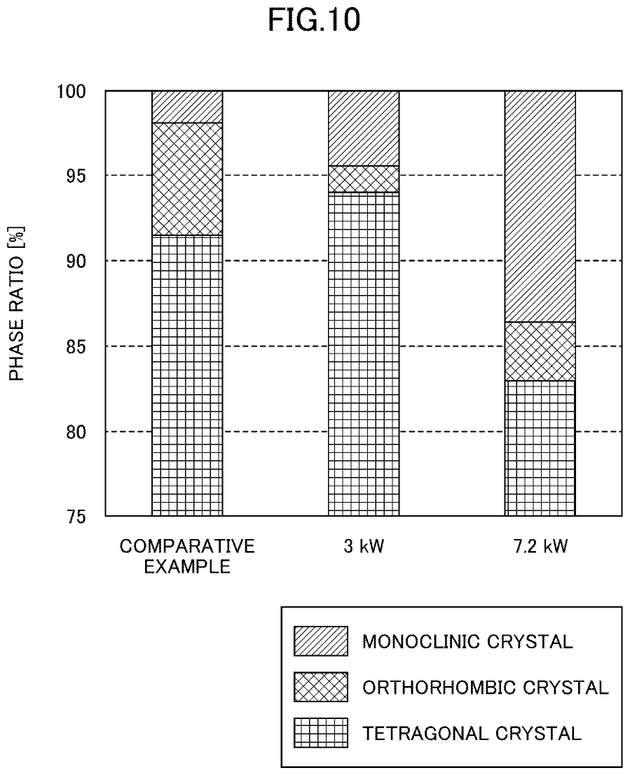

FIG. 10 is a chart depicting crystal phase ratios of the zirconium oxide film. In FIG. 10, the left column represents the result of Comparative Example, the middle column represents the result of Example with the plasma output of 3 kW, and the right column represents the result of Example with the plasma output of 7.2 kW.

As depicted in FIG. 10, it was demonstrated that the ratio of the tetragonal crystal was reduced and the ratio of the orthorhombic crystal and the ratio of the monoclinic crystal were increased by changing the output of the plasma from 3 kW to 7.2 kW. These results indicate that crystal phase ratios of the zirconium oxide film can be controlled by adjusting the output of the plasma.

The embodiments and examples disclosed above are illustrative in all respects and not restrictive. The above embodiments and examples may be modified in various forms, such as omission, substitution, and replacement, without departing from the scope and spirit of the present disclosure.

The above embodiments have been described through the example where the film-forming apparatus is a semi-batch processing film-forming apparatus, but the film-forming apparatus of the present disclosure is not limited to the semi-batch processing film-forming apparatus. For example, the film-forming apparatus may be a single-wafer processing apparatus where substrates are processed one by one. For example, the film-forming apparatus may be a batch processing apparatus where multiple substrates are simultaneously processed.

As has been described above, the present disclosure can provide a technique capable of controlling crystallinity of a thin film.

What is claimed is:

1. A film-forming method for forming a thin film on a substrate, the film-forming method comprising:
(a) adsorbing a raw material gas onto the substrate;
(b) supplying an oxidizing gas to the substrate to oxidize the raw material gas;
(c) exposing the substrate to a plasma formed using a plasma gas including an argon gas and an oxygen gas, where (c) includes adjusting an output of the plasma to control crystallinity of the thin film formed on the substrate; and
(d) repeating (a), (b), and (c) in this order.

2. The film-forming method according to claim 1, wherein the raw material gas is oxidized through thermal oxidation in (b).

3. The film-forming method according to claim 1, wherein the plasma is generated by a remote plasma unit.

4. The film-forming method according to claim 1, wherein the oxidizing gas is an ozone gas.

5. The film-forming method according to claim 1, wherein the thin film is a high-k film.

6. The film-forming method according to claim 1, wherein the substrate is arranged on a rotary table in a circumferential direction of the rotary table, the rotary table being disposed in a vacuum chamber,
an adsorption region, an oxidation region, and a plasma region are disposed above the rotary table in a circumferential direction of the rotary table inside the vacuum chamber, where (a) is performed in the adsorption region, (b) is performed in the oxidation region, and (c) is performed in the plasma region, and
the rotary table is rotated in a state in which the raw material gas is supplied to the adsorption region, the oxidizing gas is supplied to the oxidation region, and the plasma gas is supplied to the plasma region, thereby performing (d) on the substrate.

7. A film-forming apparatus that forms a thin film on a substrate, the film-forming apparatus comprising:
a vacuum chamber configured to accommodate the substrate;
a gas supply configured to supply a raw material gas, an oxidizing gas, and a plasma gas including an argon gas and an oxygen gas into the vacuum chamber;
a plasma unit configured to form a plasma using the plasma gas; and
a controller configured to control the gas supply and the plasma unit to perform
(a) adsorbing the raw material gas onto the substrate,
(b) supplying the oxidizing gas to the substrate to oxidize the raw material gas,
(c) exposing the substrate to a plasma formed using the plasma gas, and
(d) repeating (a), (b), and (c) in this order.
